(19) United States
(12) Patent Application Publication
(10) Pub. No.: US 2016/0133795 A1
(43) Pub. Date: May 12, 2016

(54) METHOD FOR MANUFACTURING LIGHT-EMITTING DEVICE

(71) Applicant: FUJIFILM Corporation, Tokyo (JP)

(72) Inventor: Yoshihisa USAMI, Kanagawa (JP)

(73) Assignee: FUJIFILM Corporation, Tokyo (JP)

(21) Appl. No.: 14/995,641

(22) Filed: Jan. 14, 2016

Related U.S. Application Data
(63) Continuation of application No. PCT/JP2014/064903, filed on Jun. 5, 2014.

(30) Foreign Application Priority Data
Aug. 2, 2013 (JP) 2013-161599

(51) Int. Cl. H01L 33/44; H01L 51/56; H01L 51/00; H01L 33/38

(52) U.S. Cl. CPC H01L 33/44; H01L 33/38; H01L 51/56; H01L 51/0021; H01L 51/0024; H01L 2933/0025; H01L 2933/0016

(57) ABSTRACT

Provided is a method of manufacturing a light-emitting device, the method including: a step of providing a conductive material on both surfaces of a base material in which a plurality of light-emitting elements each including a first electrode and a second electrode facing each other are formed, and cutting out the light-emitting elements together with the conductive material from the base material, to thereby obtain the light-emitting elements in each of which the first electrode and the second electrode are provided with conductive members having substantially the same sizes as those of the first electrode and the second electrode; a step of mixing the light-emitting elements with a binder having an insulating property to obtain a coating liquid, and applying the coating liquid onto a first substrate having a conductive layer formed thereon, to thereby form a coating layer; a step of laminating a second substrate having a conductive layer formed thereon on the first substrate so that the coating layer is interposed between the first and second substrates; and a step of applying pressure in a lamination direction in which the first substrate and the second substrate are laminated on each other, and holding the substrates at a preset temperature for a preset period of time in a state where the pressure is applied.

### CROSS-REFERENCE TO RELATED APPLICATIONS

This application is a Continuation of PCT International Application No. PCT/JP2014/064903 filed on Jun. 5, 2014, which claims priority under 35 U.S.C. §119(a) to Japanese Patent Application No. 2013-161599 filed on Aug. 2, 2013. The above application is hereby expressly incorporated by reference, in its entirety, into the present

### BACKGROUND OF THE INVENTION

1. Field of the invention

The present invention relates to a method of manufacturing a light-emitting device in which a light-emitting element such as an inorganic light-emitting element or an organic light-emitting element is provided using a coating method, and more particularly, to a method of manufacturing a light-emitting device which facilitates the manufacture of the light-emitting device.

2. Description of the Related Art

At present, backlight units of thin displays, planar illumination devices, and the like are required to be made thin. Light-emitting devices using an LED chip have been proposed.

In light-emitting devices using an LED chip of the related art, an electrode is attached to the LED chip by die bonding with the electrode facing upward, and the electrode of the LED chip and a wiring of a substrate are connected to each other by wire bonding, thereby mounting the LED chip on the substrate. In addition, an LED chip is mounted on a substrate using a flip chip method in which an electrode of the LED chip is placed on the lower side of the LED chip, and the lower electrode and a wiring of the substrate are connected to each other using a conductive material. In this case, it is necessary to adjust the positions of the LED chip and the wiring of the substrate.

Consequently, a method of mounting an LED chip without positioning the LED chip has been proposed (for example, see JP2009-10204A and US2012/0164796A).

In the light-emitting device disclosed in JP2009-10204A, an upper electrode and a lower electrode of an LED chip are connected to a conductive layer of a conductive sheet using an anisotropic conductive resin, and the vicinity of the LED chip is filled with a non-conductive adhesive containing insulating beads.

US2012/0164796A discloses an illumination device using a diode (for example, see FIGS. 1 to 3) having a substantially hexagonal pillar shape (for example, see FIGS. 76 to 79). The patent document discloses that a diode having a width of approximately 10 μm to 50 μm and a height of approximately 5 μm to 25 μm is used as the diode.

US2012/0164796A discloses that diode ink having diodes dispersed in a solvent is applied using a coating method, and the diodes are provided in a conductive layer. Further, the patent document discloses that the diode ink can be printed on, for example, an LED-based illumination device or other flexible sheets. Meanwhile, the diode ink contains a plurality of particles which are substantially chemically inert.

### SUMMARY OF THE INVENTION

In manufacturing the above-described light-emitting device disclosed in JP2009-102040A, it is necessary to attach an anisotropic conductive resin for each LED chip, and thus there is a problem in that a manufacturing process becomes complicated.

In addition, in US2012/0164796A described above, it is necessary to process a diode into a special shape such as a substantially hexagonal pillar shape, and thus there is a problem in that a manufacturing process becomes complicated and a manufacturing cost is increased.

An object of the present invention is to solve such problems of the related art and to provide a method of manufacturing a light-emitting device which facilitates the manufacture of the light-emitting device.

In order to accomplish the above-mentioned object, the present invention provides a method of manufacturing a light-emitting device, the method including: a step of providing a conductive material on both surfaces of a base material in which a plurality of light-emitting elements each including a first electrode and a second electrode facing each other are formed, and cutting out the light-emitting elements together with the conductive material from the base material, to thereby obtain the light-emitting elements in each of which the first electrode and the second electrode are provided with conductive members having substantially the same sizes as those of the first electrode and the second electrode; a step of mixing the light-emitting elements with a binder having an insulating property to obtain a coating liquid, and applying the coating liquid onto a first substrate having a conductive layer formed thereon, to thereby form a coating layer; a step of laminating a second substrate having a conductive layer formed thereon on the first substrate so that the coating layer is interposed between the first and second substrates; and a step of applying pressure in a lamination direction in which the first substrate and the second substrate are laminated on each other, and holding the substrates at a preset temperature for a preset period of time in a state where the pressure is applied.

It is preferable that the conductive member is transparent. In addition, it is possible to use, for example, an inorganic light-emitting element or an organic light-emitting element as the light-emitting element.

According to the invention, it is possible to easily manufacture a light-emitting device. In addition, conductive members provided in the light-emitting element are formed to have substantially the same sizes as those of a first electrode and a second electrode. Accordingly, the amount of light absorbed into the conductive member in light emitted from the light-emitting element is reduced, and thus it is possible to effectively use the light emitted from the light-emitting element.

### BRIEF DESCRIPTION OF THE DRAWINGS

FIG. 1 is a flowchart illustrating a method of manufacturing a light-emitting device according to an embodiment of the invention.

FIGS. 2A to 2C are schematic perspective views illustrating a method of manufacturing an LED chip, used in the light-emitting device according to the embodiment of the invention, in the order of steps.

FIG. 3 is a schematic diagram illustrating a manufacturing device used for the manufacture of the light-emitting device according to the embodiment of the invention.

FIGS. 4A to 4C are cross-sectional views illustrating the method of manufacturing a light-emitting device according to the embodiment in the order of steps.

FIG. 5 is a cross-sectional view illustrating a light-emitting device obtained by the method of manufacturing a light-emitting device according to the embodiment of the invention.

FIG. 6A is a schematic plan view illustrating an example of an arrangement state of the light-emitting elements, and FIG. 6B is a schematic plan view illustrating another example of an arrangement state of light-emitting elements.

FIG. 7A is a schematic plan view illustrating another example of a light-emitting device obtained by the method of manufacturing a light-emitting device according to embodiment of the invention, and FIG. 7B is an enlarged view illustrating a main portion shown in FIG. 7A.

FIG. 8A is a cross-sectional view illustrating an illumination device using the light-emitting device obtained by the method of manufacturing a light-emitting device according to the embodiment of the invention, and FIG. 8B is a plan view illustrating a display device using the light-emitting device obtained by the method of manufacturing a light-emitting device according to the embodiment of the invention.

### DESCRIPTION OF THE PREFERRED EMBODIMENTS

Hereinafter, a method of manufacturing a light-emitting device of the present invention will be described in detail on the basis of a preferred embodiment shown in the accompanying drawings.

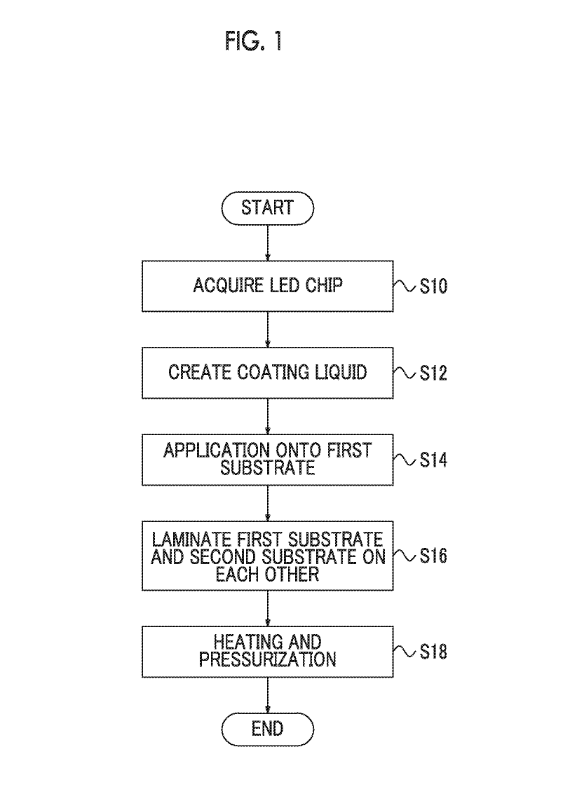

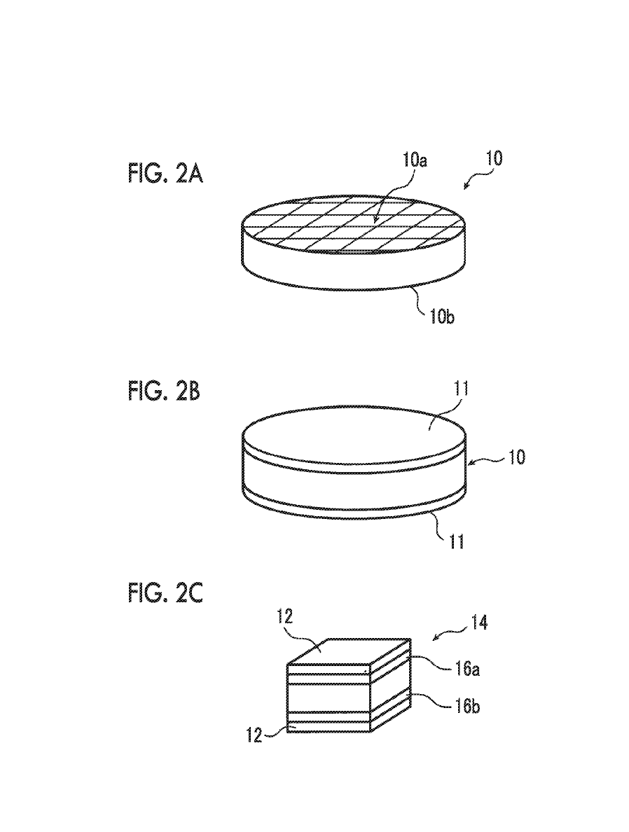

FIG. 1 is a flowchart illustrating a method of manufacturing a light-emitting device according, to an embodiment of the invention. FIGS. 2A to 2C are schematic perspective views illustrating a method of manufacturing an LED chip, used in the light-emitting device according to the embodiment of the invention, in the order of steps.

In the method of manufacturing, a light-emitting device of the present embodiment, for example, an LED chip including an upper electrode and a lower electrode facing each other is used as the light-emitting element. Each of the electrodes of the LED chip is provided with a conductive member having substantially the same size as that of the electrode. In the light-emitting device, an insulating resin layer is provided between a pair of substrates on which a conductive layer is formed, the LED chip is disposed in the resin layer, and each electrode and a conductive layer are electrically connected to each other through the conductive member.

Hereinafter, the method of manufacturing a light-emitting device of the present embodiment will be described in detail.

In the method of manufacturing a light-emitting device of the present embodiment, first, for example, an LED chip is acquired as a light-emitting element (step S10).

In step S10, as illustrated in FIG. 2A, first, an LED wafer 10 (base material) having a plurality of LED chips (not shown in FIG. 2A) formed therein is prepared.

Next, a conductive layer 11 is provided on a surface 10a and a rear surface 10b of the LED wafer 10 as illustrated in FIG. 2B. A method of forming the conductive layer 11 is not particularly limited. For example, the conductive layer 11 may be formed by sticking on a sheet having a conductive property, or may be formed by applying a conductive adhesive. The conductive layer 11 is equivalent to a conductive material of the invention.

The conductive layer 11 has a configuration which is not particularly limited insofar as the conductive layer has a conductive property, and may be formed of for example, ITO, ZnO, or a conductor containing Ag nanoparticles or Ag nanowires. In addition, the conductive layer 11 may be formed of an anisotropic conductive adhesive. Meanwhile, the conductive layer 11 is preferably transparent, but at least one of the surface 10a side and the rear surface 10b side may be opaque.

Here, the term “transparent” as used herein means that an average transmittance in an emission wavelength range of a light-emitting element is preferably equal to or higher than 50%, is further preferably equal to or higher than 80%, and is most preferably equal to or higher than 90% as a transmittance. The phrase “emission wavelength range” as used herein refers to a range in which the amount of light has a peak intensity of equal to or higher than 10%. Meanwhile, even when the term “transparent” is not particularly mentioned below, the term “transparent” has a meaning specified above. The term “opaque” as used herein has a meaning that does not satisfy the above-described specification of the term “transparent”.

Next, as illustrated in FIG. 2B, after the conductive layer 11 is formed on the LED wafer 10, the LED chip is cut out from the LED wafer 10 together with the conductive layer 11, thereby obtaining an LED chip 14 as illustrated in FIG. 2C. Electrodes are formed in the LED chip 14 so as to correspond to the surface 10a and the rear surface 10b of the LED wafer 10, and thus the LED chip 14 includes an upper electrode 16a and a lower electrode 16b which face each other. For example, in the LED chip 14, light is emitted from the upper electrode 16a side and the lower electrode 16b side.

In the LED chip 14 illustrated in FIG. 2C, conductive members 12 are provided so as to have substantially the same sizes as those of the upper electrode 16a and the lower electrode 16b.

Meanwhile, the upper electrode 16a is equivalent to a first electrode of the invention, and the lower electrode 16b is equivalent to a second electrode of the invention.

Next, the LED chips 14 obtained are put in and are mixed with a binder such as, for example, an insulating adhesive, thereby obtaining a coating liquid for applying the LED chips 14 onto a substrate (step S12). Examples of the insulating adhesive to he used include a thermosetting resin agent, a thermoplastic resin agent, a synthetic rubber, and the like. A viscosity adjusting agent, a solvent, particles serving as spacers, particles for improving optical characteristics, and the like can he appropriately added to the coating liquid. The particles serving as spacers and the particles for improving optical characteristics may be fillers.

In addition, the amount of LED chips 14 contained in the coating liquid is an amount corresponding to a ratio of an area of the LED chips 14 to that of the substrate.

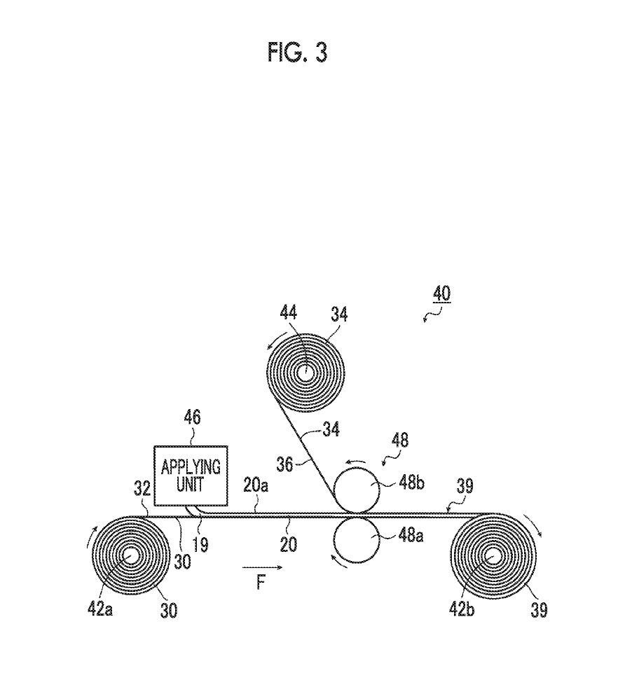

Next, the light-emitting device of the present embodiment is manufactured using, for example, a manufacturing device 40 illustrated in FIG. 3.

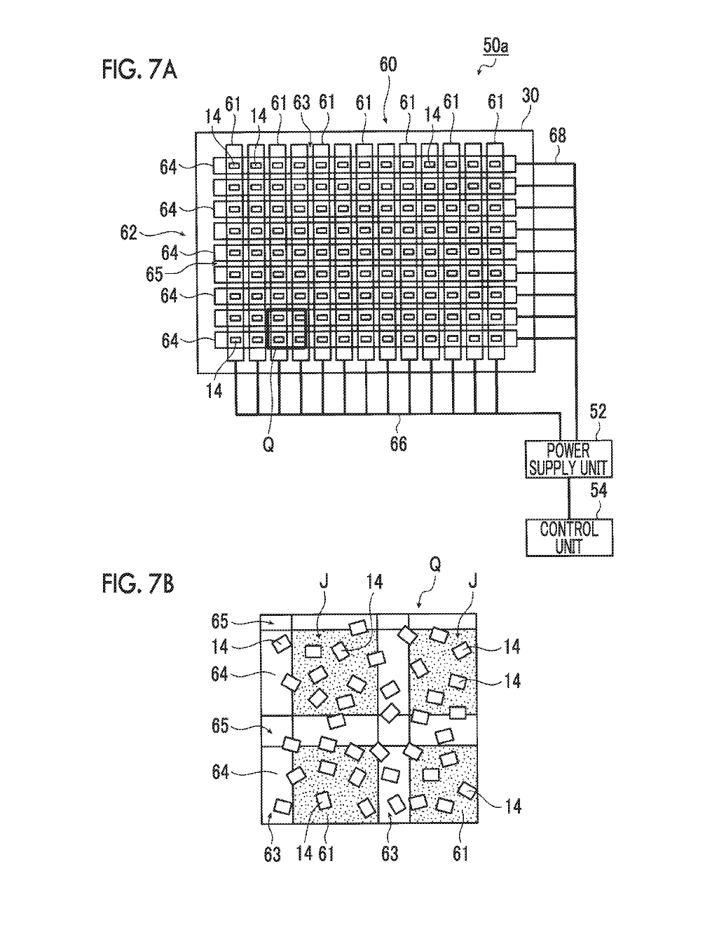

Hereinafter, the manufacturing device 40 used for the manufacture of the light-emitting device illustrated in FIGS. 7A and 7B will be described.

The manufacturing device 40, which is a roll-to-roll type device, includes a rotating shaft 42a around which the first substrate 30, having a conductive layer 32 formed thereon, is wound in a roll shape, a rotating shaft 44 around which the second substrate 34, having a conductive layer 36 formed thereon, is wound in a roll shape, an applying unit 46, a roller pair 48 that laminates the second substrate 34 on the first substrate 30 and applies pressure and heat thereto, and a winding shaft 42b around which a laminate 39, having the second substrate 34 and the first substrate 30 laminated on each other and being subjected to heating and pressurization, is wound in a roll shape.

The applying unit 46 applies the above-mentioned coating liquid onto the conductive layer 32 of the first substrate 30 to thereby form a coated film 20. For example, slit coating, bar coating, or a screen printing method is used to apply a coating liquid 19.

The roller pair 48, including rollers 48a and 48b provided with a heater therein, draws in the second substrate 34 by the roller 48b and performs heating and pressurization for a predetermined period of time at a pressure and a temperature which are set in advance while laminating the second substrate on the first substrate 30 having the coated film 20 formed thereon, thereby obtaining the laminate 39.

In the roller pair 48, power in a transport direction F is applied to the LED chip 14 by gradually increasing a pressure of the roller 48b on the roller 48a from the initial stage during the pressurization and heating, so that the upper electrode 16a of the LED chip 14 can be made to face the conductive layers 32 and 36.

In addition, power in the transport direction F is applied to the LED chip 14 also by gradually increasing a rotation speed of the roller 48b with respect to the roller 48a from the initial stage, so that the upper electrode 16a of the LED chip 14 can be made to face the conductive layers 32 and 36. This control can be performed with a higher degree of accuracy by installing a plurality of rollers for pressurization and heating.

Since a certain degree of pressure is applied in a wound state, it is also possible to further increase adhesion by further performing heating.

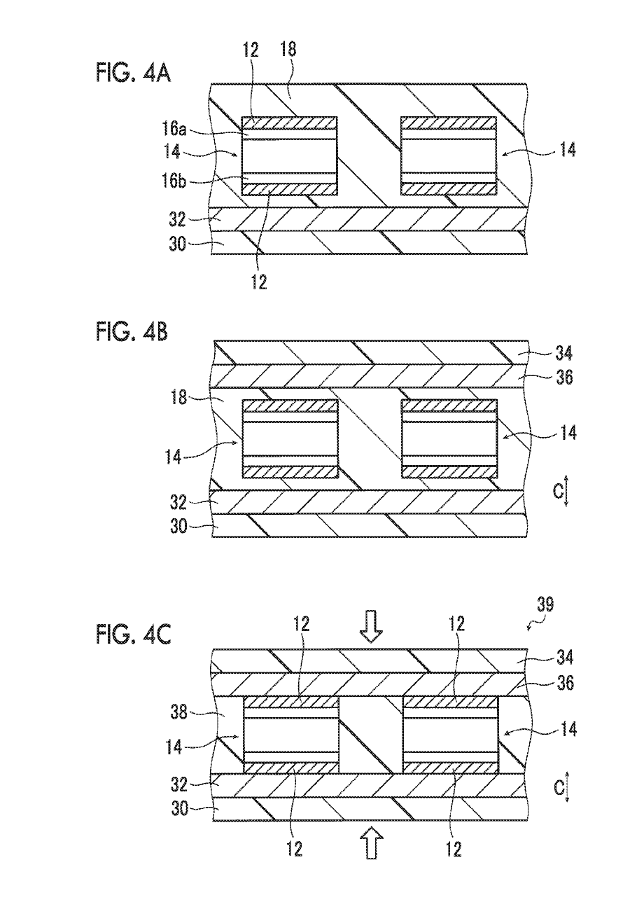

In the manufacturing device 40, the first substrate 30 unwound from the rotating shaft 42a is wound around the winding shaft 42b in advance through the roller pair 48. The coating liquid 19 containing the LED chips 14 and the insulating adhesive 18 is applied onto the conductive layer 32 of the first substrate 30 from the applying unit 46 while winding the first substrate 30 around the winding shaft 42b in the transport direction F (step S14), thereby forming the coated film 20 on the conductive layer 32 of the first substrate 30 (sec FIG. 4A). Accordingly, the LED chips 14 are disposed on the conductive layer 32 of the first substrate 30. At this time, in the LED chips 14, it is preferable that the orientations of the electrodes are aligned so that the lower electrodes 16b face the conductive layer 32, However, the orientations of the electrodes are not required to be aligned, and electrodes having different orientations may be jointly present. Thereby, it is possible to dispose the LED chip 14 simly by forming the coated film 20 using the coating liquid 19 containing the LED chips 14.

In addition, at the time of forming the coated film 20, the surface 20a (see FIG. 3) thereof may be made even so that the LED chip 14 has an orientation in which the lower electrode 16b of the LED chip 14 faces the conductive layer 32. Thereby, it is possible to prevent the electrode of the LED chip 14 from being set not to face the conductive layers 32 and 36.

Next, the second substrate 34 having a roll shape is rewound to be wound around the roller 48b of the roller pair 48, and the first substrate 30 and the second substrate 34 are laminated in a lamination direction C on each other as illustrated in FIG. 4B while transporting the first substrate 30 in the transport direction F (step S16). At this time, the rollers 48a and 48b are set to be at a preset temperature, and are held for a predetermined period of time at a predetermined temperature and perform heating and pressurization while applying pressure in the lamination direction C in which the first substrate 30 and the second substrate 34 are laminated on each other as illustrated in FIG. 4C simultaneously with the lamination (step S18). The heating and pressurization are performed under conditions such as, for example, a temperature of 150° C. and a period of time of 10 seconds.

Accordingly, the upper electrode 16a and the lower electrode 16b are electrically connected to the conductive layers 32 and 36 in accordance with the orientation of the LED chip 14 with respect to the lamination direction C, and a resin layer 38 surrounding the vicinity of the LED chip 14 is formed between the second substrate 34 and the first substrate 30, thereby obtaining the laminate 39. The laminate 39 is wound around the winding shaft 42b in a roll shape.

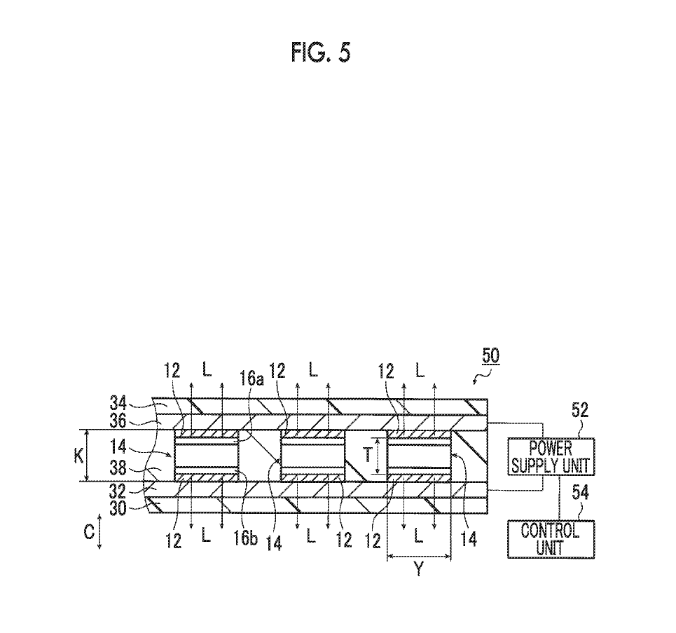

Thereafter, the laminate 39 is cut off into a preset size, and it is possible to obtain a light-emitting device 50 by connecting a power supply unit 52 to the conductive layers 32 and 36 and connecting a control unit 54 to the power supply unit 52 as illustrated in FIG. 5.

The power supply unit 52 applies a voltage to the LED chip 14 through the conductive layers 32 and 36, and can generate a direct--current voltage or an alternating-current voltage. The control unit 54 generates a direct-current voltage or an alternating-current voltage in the power supply unit 52 and applies the direct-current voltage or the alternating-current voltage to the LED chip 14. Thereby, it is possible to emit light beams L from the first substrate 30 and the second substrate 34.

In the method of manufacturing a light-emitting device of the present embodiment, after the conductive layer 11 is formed on the entire surface 10a and rear surface 10b of the LED wafer 10, the LED chip 14 is cut out together with the conductive layer 11, and thus it is possible to easily obtain the LED chip 14 provided with the conductive members 12 having substantially the same sizes as those of the upper electrode 16a and the lower electrode 16b. It is possible to easily manufacture the light-emitting device 50 by applying a coating liquid containing the LED chips 14 onto the first substrate 30, laminating the second substrate 34 thereon, and performing heating and pressurization.

Further, the conductive members 12 are formed to have substantially the same sizes as those of the upper electrode 16a and the lower electrode 16b so that the amount of light absorbed into the conductive member 12 in light emitted from the LED chip 14 is reduced, and thus it is possible to effectively use the light emitted from the LED chip 14.

Meanwhile, the method of manufacturing a light-emitting device is not limited to a roll-to-roll type, and a sheet type can also be used. In this case, in heating and pressurization steps, the first substrate 30 and the second substrate 34 are pressed with a preset pressure with, for example, a pair of flat plates interposed therebetween in the lamination direction C thereof, are heated at a preset temperature, and are held for a preset period of time.

In addition, in the manufacturing method of the present embodiment, a method of creating and applying a coating liquid is used, but the present invention is not limited thereto. An insulating adhesive may be applied, the LED chips 14 may be scattered thereon, and an insulating adhesive may be applied again so as to cover the LED chips 14.

Since the first substrate 30, the second substrate 34, and the conductive layers 32 and 36 are configured to be flexible, it is possible to configure the light-emitting device 50 which is flexible as a whole.

In addition, in the LED chip 14, the polarities of the upper electrode 16a and the lower electrode 16b are not particularly limited insofar as one of the electrodes has a positive polarity and the other has a negative polarity. The upper electrode 16a and the lower electrode 16b may be transparent or opaque. In the case of opaque electrodes, light is emitted from the lateral side of the LED chip 14. In addition, the wavelength of the light emitted from the LED chip 14 is not particularly limited.

The shape of the LED chip 14 is not particularly limited. As illustrated in FIG. 5, in the LED chip 14, when a thickness is set to be T (μm) and a width is set to be Y (μm), it is preferable that the relation of T×1.5≦Y is satisfied. In the case of a rectangular parallelepiped shape, a smallest dimension is set to be Y. Since the LED chip 14 is configured to have such a shape, there is a tendency for the lower electrode 16b of the LED chip 14 to face the conductive layers 32 and 36 at the time of applying a coating liquid containing the LED chips 14.

The shape of the LED chip 14 may not be a rectangular parallelepiped shape, and may be a hexagonal pillar shape, an octagonal pillar shape, or the like. At this time, regarding a width, the shortest diagonal line is set to be Y.

in addition, when a distance between the first substrate 30 and the second substrate 34 is set to be K (μm), it is preferable that the relation of K<Y is satisfied. Accordingly, when the second substrate 34 is laminated on the first substrate 30, the upper electrode 16a and the lower electrode 16b of the LED chip 14 easily face the conductive layers 32 and 36. Meanwhile, the distance K between substrates is approximately 10 μm to 500 μm.

Regarding the conductive member 12 provided in the LED chip 14, the length of the conductive member 12 in a width direction may be set to be larger than the above-mentioned width Y in order for the upper electrode 16a and the lower electrode 16b of the LED chip 14 to easily face the conductive layers 32 and 36 during the application,

In the present embodiment, a description is given by taking the LED chip 14 as an example of the light-emitting element. However, the present invention is not limited thereto, and an inorganic light-emitting element or an organic light-emitting element can be used. For example, an inorganic EL chip or an organic EL chip can be used.

As described above, it is preferable that the orientations of the LED chips 14 with respect to the lamination direction C are aligned, but LED chips having different orientations may be jointly present. When the LED chips 14 having different orientations with respect to the lamination direction C are jointly present, it is possible to make the LED chip 14 emit light by applying an alternating-current voltage.

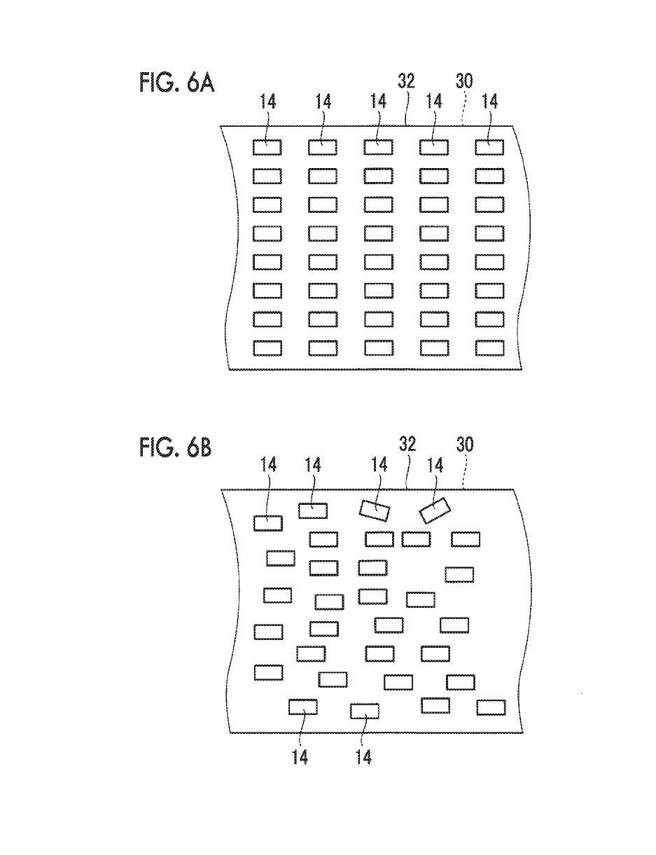

The arrangement of the LED chips 14 is not particularly limited. For example, it is preferable that the LED chips are regularly arranged as illustrated in FIG. 6A, but the LED chips may be randomly arranged as illustrated in FIG. 6B. Even in this case, the orientations of the LED chips 14 with respect to the lamination direction C may be aligned as described above, or LED chips having different orientations with respect to the lamination direction C may be jointly present.

For example, a ratio of an area of the LED chips 14 to that of the first substrate 30 is, for example, 0.01% to 90%, preferably 0.1% to 50%, and further preferably 1% to 30%.

In the present embodiment, it is preferable that both the first substrate 30 and the second substrate 34 are transparent. However, both the substrates do not necessarily have to be transparent, and at least one of the substrates may be opaque. In addition, one of the substrates may be transparent, and the other may reflect light.

The first substrate 30 and the second substrate 34 can be formed of, for example, triacetyl cellulose (TAC), polyethylene terephthalate (PET), polyethylene naphthalate (PEN), syndiotactic polystyrene (SPS), polyphenylene sulfide (PPS), polycarbonate (PC), polyarylate (PAr), polysulfone (PSF), polyester sulfone (PES), polyetherimide (PEI), cyclic polyolefin, polyimide (PI), or the like. In this manner, when a resin is used for the substrates, the substrates can be configured to be flexible as described above. Meanwhile, the first substrate 30 and the second substrate 34 may be formed using a glass substrate.

The conductive layers 32 and 36 are formed of for example, ITO, ZnO, or a conductor containing Ag nanoparticles or Ag nanowires. It is preferable that both the conductive layers 32 and 36 are transparent. However, both the layers do not necessarily have to be transparent, and at least one of the layers may be opaque.

In addition, the conductive layers 32 and 36 do not cover the entirety of the surfaces of the substrate and are omitted from a portion thereof, so that light may pass therethrough. In addition, when the LED chip 14 has a sufficient conductivity, the conductive layers 32 and 36 may not be present.

The resin layer 38 is formed of an insulator as described above and is a layer according to a composition of a binder such as an insulating adhesive of the coating liquid 19. The resin layer 38 may include particles serving as spacers, particles for improving optical characteristics, and the like. Meanwhile, it is preferable that the resin layer 38 is transparent.

The light-emitting device manufactured in the present invention is not limited to the light-emitting device 50 illustrated in FIG. 5, and may have a configuration of a light-emitting device 50a illustrated in FIGS. 7A and 7B. FIG. 7B is an enlarged view of a region Q shown in FIG. 7A, in the light-emitting device 50a illustrated in FIG. 7A, the same components as those of the light-emitting device 50 illustrated in FIG. 5 are denoted by the same reference numerals and signs, and a detailed description thereof will not be repeated here.

In the light-emitting device 50a illustrated in FIG. 7A, conductive layers 60 and 62 are formed in a striped pattern, and a first substrate 30 and a second substrate 34 are disposed so as to configure a lattice in which the conductive layer 60 and the conductive layer 62 are perpendicular to each other. Meanwhile, the conductive layer 60 corresponds to the conductive layer 36 of the light-emitting device 50, and the conductive layer 62 corresponds to the conductive layer 32 of the light-emitting device 50.

In the conductive layer 60, conductive portions 61 are connected to a power supply unit 52 through a wiring 66. In the conductive layer 62, conductive portions 64 are connected to the power supply unit through a wiring 68.

A voltage is applied to an LED chip 14 provided between each of the conductive portions 61 of the conductive layer 60 and each of the conductive portions 64 of the conductive layer 62 in a lamination direction C (see FIG. 5) in which the first substrate 30 and the second substrate 34 are laminated on each other, whereby light is emitted. In the light-emitting device 50a, LED chips 14 located at any position between each of the conductive portions 61 of the conductive layer 60 and each of the conductive portions 64 of the conductive layer 62, that is, at an intersection point between the conductive portion 61 and conductive portion 64 can be made to emit light using a method which is generally called a matrix driving method.

In the light-emitting device 50a, as illustrated in FIG. 7B, it is preferable that a plurality of LED chips 14 are present at each intersection point J between the conductive portion 61 and the conductive portion 64. In addition, it is preferable that the length of the longest diagonal line of the LED chip 14 is smaller than the width between the conductive layers 60 (width of a region 63 between the conductive portions 61) and the width between the conductive layers 62 (width of a region 65 between the conductive portions 64) from the viewpoint of suppressing a short circuit.

In the light-emitting device 50a, the arrangement state of the LED chips 14 is not particularly limited insofar as the LED chips are arranged on the conductive layers 60 and 62. The LED chips 14 may be present in the region 63 between the conductive portions 61 of the conductive layer 60 and the region 65 between the conductive portions 64 of the conductive layer 62 in the plane direction of the substrate. In this case, a voltage is not supplied to the LED chips 14 which are not present between the conductive layer 60 and the conductive layer 62 in the lamination direction in which the first substrate 30 and the second substrate 34 are laminated on each other, and thus light is not emitted. However, the arrangement of the LED chips 14 is not limited, and thus it is possible to reduce the accuracy of positioning and to provide the LED chips 14 simply by applying a coating liquid containing the LED chips 14 as described above.

Meanwhile, also in the light-emitting device 50a, even when the orientations of the LED chips 14 with respect to the lamination direction C are aligned, LED chips having different orientations may be jointly present. A direct-current voltage is applied when all of the orientations of the LED chips 14 with respect to the lamination direction C are aligned, and an alternating-current voltage is applied when the LED chips having different orientations are jointly present.

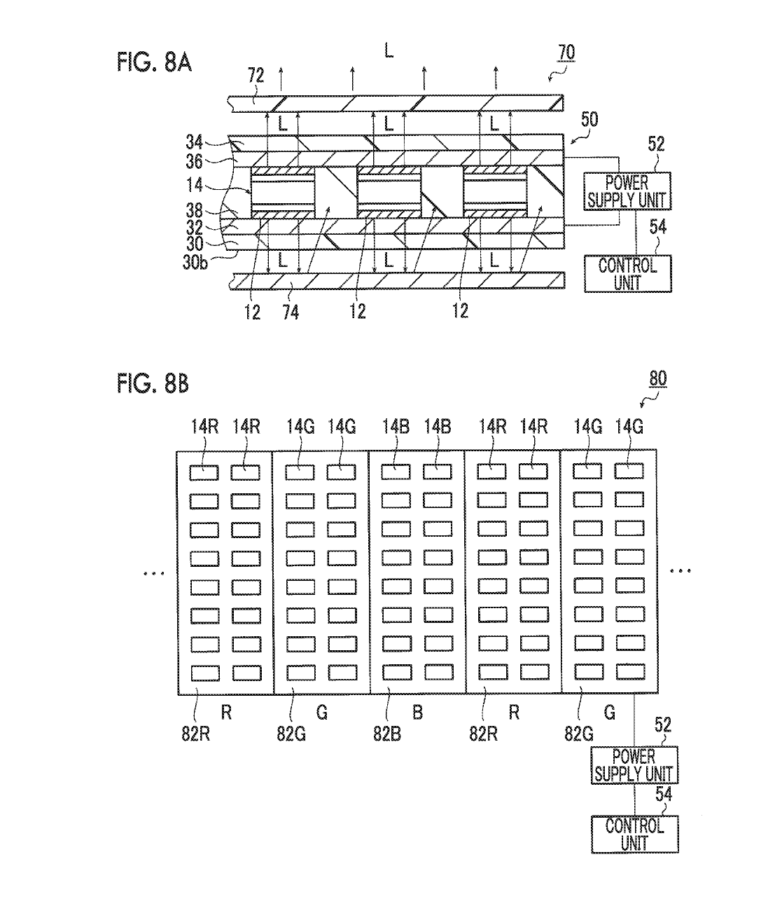

The light-emitting devices 50 and 50a described above can be applied to, for example, an illumination device illustrated in FIG. 8A.

In an illumination device 70 illustrated in FIG. 8A, a scattering plate 72 is disposed on the second substrate 34 of the light-emitting device 50, and a reflective plate 74 is disposed below a lower surface 30b of a first substrate 30 of the light-emitting device 50. In the illumination device 70, LED chips 14 are made to emit light, and thus light beams L emitted to the second substrate 34 side pass through the scattering plate 72 and are emitted to the outside, and light, beams L emitted to the first substrate 30 side arc reflected to the second substrate 34 side by the reflective plate 74 and are emitted to the outside from the scattering plate 72. A known plate can be appropriately used as the scattering, plate 72 and the reflective plate 74. In addition, the scattering plate may also serve as the second substrate 34, and the reflective plate may also serve as the first substrate 30.

Meanwhile, in the illumination device 70, the light-emitting device 50a illustrated in FIGS. 7A and 7B can also be used instead of the light-emitting device 50 illustrated in FIG. 5. In this case, an LED chip 14 located at a specific position can be made to emit light by a matrix driving method. Also when the light-emitting device 50a is used, the scattering plate may also serve as the second substrate 34, and the reflective plate may also serve as the first substrate 30.

Further, when the light-emitting device 50a is used, it is preferable that one of the plurality of LED chips 14 is present at every intersection point J between the conductive portion 61 and the conductive portion 64 as described above (see FIG. 7B). It is also preferable that the length of the longest diagonal line of the LED chip 14 is smaller than a width between the conductive layers 60 and a width between the conductive layers 62 from the viewpoint of preventing a short circuit as described above.

In addition, the first substrate 30, the second substrate 34, and conductive layers 32 and 36 of the light-emitting device 50 are configured to be flexible, and thus it is possible to configure the flexible illumination device 70 which is bendable. Also when the light-emitting device 50a is used, the first substrate 30, the second substrate 34, and conductive layers 60 and 62 are configured to be flexible, and thus it is possible to configure the flexible illumination device 70 which is bendable.

In addition, a display device 80 illustrated in FIG. 8B can be configured by using light-emitting elements with three primary colors of red, green, and blue. In this case, a plurality of LED chips 14R emitting red light are disposed to configure a red pixel 82R, a plurality of LED chips 14G emitting green light are disposed to configure a green pixel 82G, and a plurality of LED chips 14B emitting blue light are disposed to configure a blue pixel 82B. The red pixel 82R, the green pixel 82G, and the blue pixel 82B are connected to a power supply unit 52, and a voltage is applied from the power supply unit 52, and thus the LED chips 14R, the LED chips 14G, and the LED chips 14B emit the respective colors of light. The application of the voltage from the power supply unit 52 is controlled by a control unit 54. The control unit 54 displays an image by making the red pixel 82R, the green pixel 82G, and the blue pixel 82B emit light at a preset light emission timing for a preset period of time, for example, in accordance with an object to be displayed. It is preferable that the orientations of the LED chips 14R, the LED chips 14G, and the LED chips 14B are aligned.

Meanwhile, the display device 80 is configured such that the red pixel 82R, the green pixel 82G, and the blue pixel 82B are disposed similar to a known display device, and can display an image using a known driving method.

When a pixel is constituted by one light-emitting element, a pixel cannot be displayed in a case where the light-emitting element becomes defective. On the other hand, the display device 80 can be configured so that a plurality of light-emitting elements constitute one pixel, and thus a defect of a light-emitting element becomes inconspicuous. Further, the brightness of a pixel in which a defect has occurred in a light-emitting element is increased, and thus the pixel may have the same amount of light as those of peripheral pixels. Further, a known control circuit constituted by a TFT element or the like is disposed. for each pixel, and thus it is possible to perform control with a higher degree of accuracy.

The present invention is basically configured as described above. As described above, the method of manufacturing a light-emitting device of the present invention has been described in detail. However, the present invention is not limited to the above-described embodiment, and various improvements or modifications may of course be made without departing from the scope of the invention.

### EXPLANATION OF REFERENCES

10: LED WAFER
11: CONDUCTIVE LAYER
12: CONDUCTIVE MEMBER
14: LED CHIP
16a: UPPER ELECTRODE
16b: LOWER ELECTRODE
20: COATED FILM
30: FIRST SUBSTRATE
32, 36: CONDUCTIVE LAYER
34: SECOND SUBSTRATE
38: RESIN LAYER
40: MANUFACTURING DEVICE
50, 50a: LIGHT-EMITTING DEVICE
70: ILLUMINATION DEVICE
80: DISPLAY DEVICE

What is claimed is

1. A method of manufacturing a light-emitting device, the method comprising:
a step of providing a conductive material on both surfaces of a base material in which a plurality of light-emitting elements each including a first electrode and a second electrode facing each other are formed, and cutting out the light-emitting elements together with the conductive material from the base material, to thereby obtain the light-emitting elements in each of which the first electrode and the second electrode are provided with conductive members having substantially the same sizes as those of the first electrode and the second electrode;
a step of mixing the light-emitting elements with a binder having an insulating property to obtain a coating liquid, and applying the coating liquid onto a first substrate having a conductive layer formed thereon, to thereby form a coating layer;
a step of laminating a second substrate having a conductive layer formed thereon on the first substrate so that the coating layer is interposed between the first and second substrates; and
a step of applying pressure in a lamination direction in which the first substrate and the second substrate are laminated on each other, and holding the substrates at a preset temperature for a preset period of time in a state where the pressure is applied.

2. The method according to claim 1, wherein the conductive member is transparent.

3. The method according to claim 1, wherein the light-emitting element is an inorganic light-emitting element or an organic light-emitting element.

4. The method according to claim 2, wherein the light-emitting element is an inorganic light-emitting element or an organic light-emitting element.
